(19) United States
(12) Patent Application Publication
(10) Pub. No.: US 2008/0304528 A1
(43) Pub. Date: Dec. 11, 2008

(54) Nitride semiconductor laser device and fabrication method thereof

(75) Inventors: Shuichiro Yamamoto, Tenri-shi (JP); Shigetoshi Ito, Osaka (JP); Fumio Yamashita, Nara-shi (JP); Toshiyuki Kawakami, Hiroshima (JP)

Correspondence Address: HARNESS, DICKEY & PIERCE, P.L.C., P.O. BOX 8910, RESTON, VA, 20195, US

(73) Assignee: SHARP KABUSHIKI KAISHA

(21) Appl. No.: 12/155,332

(22) Filed: Jun. 3, 2008

(30) Foreign Application Priority Data
Jun. 6, 2007 (JP) 2007-150639

(51) Int. Cl. H01S 5/026; H01L 21/02

(52) U.S. Cl. 372/44.011; 438/31; 257/E21.002

(57) ABSTRACT

In a nitride semiconductor laser device so structured as to suppress development of a step on nitride semiconductor layers, the substrate has the (11-20) plane as the principal plane, the resonator end surface is perpendicular to the principal plane, and, in the cleavage surface forming the resonator end surface, at least by one side of a stripe-shaped waveguide, an etched-in portion is formed as an etched-in region open toward the surface of the nitride semiconductor layers.

This nonprovisional application claims priority under 35 U.S.C. §119(a) on Patent Application No. 2007-150639 filed in Japan on Jun. 6, 2007, the entire contents of which are hereby incorporated by reference.

### BACKGROUND OF THE INVENTION

1. Field of the Invention

The present invention relates to a nitride semiconductor laser device and to a method for fabricating it. More particularly, the invention relates to a nitride semiconductor laser device having nitride semiconductor layers laminated on a nitride semiconductor substrate having a particular planar orientation, and to a method for fabricating such a nitride semiconductor laser device.

2. Description of Related Art

Nitride semiconductors are compounds of N (nitrogen), which is a group V element, and a group III element, such as Al (aluminum), Ga (gallium), and In (indium). Because of their band structures and chemical stability, nitride semiconductors have been receiving much attention as semiconductor materials for light-emitting devices and power devices, and have been tried in various applications. Especially active is the development of nitride semiconductor laser devices that emit light in the ultraviolet to visible region as light sources for optical information recording apparatuses, illumination apparatuses, display apparatuses, sensors, etc.

In a nitride semiconductor laser device, it is common to use a nitride semiconductor substrate, that is, a substrate of the same type of material as the nitride semiconductor layers to be laminated on its surface. This helps enhance the quality of the laminated nitride semiconductor layers and thereby enhance the characteristics of the semiconductor laser device. Typically used as such a substrate is, for its ease of fabrication, a crystal having a wurtzite structure and having the (0001) plane as its principal plane. When a crystal of nitride semiconductor layers is formed on this nitride semiconductor substrate, it grows, likewise, on the (0001) plane as its principal plane.

In such a semiconductor laser device having nitride semiconductors laminated on the (0001) plane as the principal plane, that is, in the [0001] direction (in the C-axis direction), piezoelectric polarization occurs because of the difference in the lattice constants of InN and GaN in the quantum well active layer. Because the piezoelectric polarization causes a piezoelectric field which is an internal electric field in the quantum well active layer, the nitride semiconductor laser device is affected by the electron-confining Stark effect.

Accordingly, because electrons and holes are separated spatially, there is a concern over a dramatic drop in their recombination probability. As a device that has a structure to alleviate this disadvantage, there has also been studied a nitride semiconductor laser device having a laminate structure formed in the direction perpendicular to the C-axis (see JP-A-H8-213692 and JP-A-H10-51029).

In such a nitride semiconductor laser device laminated in the direction perpendicular to the C-axis, a reduced influence of the Stark effect and an increased gain due to the increased crystal asymmetry in the quantum well plane can be expected. Moreover the suppression of the penetrating dislocation, which tends to develop in the C-axis direction, developing in the lamination direction is expected to enhance crystallinity. These advantages are expected to reduce the threshold current density and bring highly reliable and high-performance device characteristics. Therefore, there has also been studied a nitride semiconductor substrate having the (11-20) plate as the principal plane.

In an expression representing a plane or orientation of a crystal, it is conventional in crystallography to signify a negative index by putting a horizontal line over its absolute value; in the present specification, however, since that notation cannot be adopted, a negative index is instead signified by putting a minus sign “−” before its absolute value.

Disadvantageously, however, the conventional nitride semiconductor laser device, the nitride semiconductor layers of which are laminated on a nitride semiconductor substrate (hereinafter, called an “a-surface nitride semiconductor substrate”) having the (11-20) plane as the principal plane with a typical process of photolithography, vacuum deposition, polishing, cleaving and coating, does not offer satisfactory characteristics to ensure its reliability. That is, when conventional nitride semiconductor devices are subjected to CW (continuous wave) oscillation (continuous oscillation) up to a high output, a certain percentage of them are damaged before reaching the point where they output enough light.

Moreover, the longer the time for driving the conventional nitride semiconductor laser devices is, the higher the percentage of the damaged deices becomes. Depending on the driving conditions, most of them can offer unsatisfactory reliability. This indicates that the conventional nitride semiconductor laser device laminated on the a-surface nitride semiconductor substrate suffers from, as inherent in its characteristics, problems that cannot be overcome with the conventional knowledge, specifically the disadvantage of an extremely low yield of good devices and the risk of sudden breakdown in a long time use.

Accordingly, the nitride semiconductor laser device was studied to confirm how the device is damaged before it reaches the point where it outputs enough light. Results of this are as follows: on the active layer of the end surface of the resonator, a step develops in parallel with the nitride semiconductor layers, causing poor flatness; furthermore, the step causes damage to the crystal nearby, and also causes poor coating film over the portion near the step and hence poor protection of the end surface, deteriorating of the resistance to damage to the end surface of the resonator.

### SUMMARY OF THE INVENTION

To cope with the conventional problems mentioned above, it is an object of the present invention to provide a nitride semiconductor laser device so structured as to suppress development of a step (unflushness) on nitride semiconductor layers. It is another object of the invention to provide a method for fabricating a nitride semiconductor laser device and its wafer with suppressed development of a step on the nitride semiconductor layers, in order thereby to improve their yield and reliability.

To achieve the above objects, according to one aspect of the invention, a nitride semiconductor laser chip is provided with: a nitride semiconductor substrate; a plurality of nitride semiconductor layers laminated on the surface of the nitride semiconductor substrate and including an active layer; a stripe-shaped waveguide formed on the nitride semiconductor layers; and a resonator (cavity) end surface formed of the cleaved surfaces of the nitride semiconductor layers, together with the nitride semiconductor substrate. Here, the principal plane of the nitride semiconductor substrate is the (11-20) plane, and the resonator end surface is perpendicular to the principal plane. Moreover, in the cleavage surface forming the resonator end surface, at least by one side of the stripe-shaped waveguide, an etched-in portion is formed as an etched-in region open toward the surface of the nitride semiconductor layers.

With this structure, it is possible to stop, with the etched-in portion, a step which develops at the end surface of the resonator during cleaving, and prevent the development of a step at the stripe-shaped waveguide.

In the nitride semiconductor laser device described above, the direction in which the stripe-shaped waveguide is formed may be the [0001] direction, and the cleavage surface forming the end surface of the resonator may be the (0001) plane. Further, the direction in which the stripe-shaped waveguide is formed may be the [1-100] direction, and the cleavage surface forming the end surface of the resonator may be the (1-100) plane.

Besides, it is preferable that the etched-in portion be formed at a distance of 2 μm to 200 μm away from the stripe-shaped waveguide. The etched-in portion may be formed into a rectangular shape on the cleavage line when the end surface of the resonator is formed, and may be formed into a striped shape parallel to the stripe-shaped waveguide.

It is preferable that a protective film be formed on the surface of the etched-in portion.

A plurality of stripe-shaped waveguides may be formed on each nitride semiconductor laser device.

According to another aspect of the present invention, a method of fabricating a nitride semiconductor laser device may include the steps of: laminating a plurality of nitride semiconductor layers including an active layer on a nitride semiconductor substrate having the (11-20) surface as the principal plane for crystal growth; forming a stripe-shaped waveguide on the nitride semiconductor layers; forming an etched-in portion in the nitride semiconductor layers as an etched-in region open toward the surface of the nitride semiconductor layers; forming, in part of a wafer having the stripe-shaped waveguide and the etched-in portion formed thereon and therein, a groove to serve as the starting point of cleavage; and applying an external force to the wafer along the groove to form a cleavage surface perpendicular to the principal plane. Here, the etched-in portion is formed at a position by a side of the stripe-shaped waveguide where the cleavage surface cuts.

The forming step of the etched-in portion may include: a dielectric masking step where on the plurality of nitride semiconductor layers laminated in the laminating step, a region other than the stripe-shaped waveguide is masked with a dielectric layer; an opening portion forming step where the dielectric layer masking the nitride semiconductor layers in the dielectric masking step is removed at the position of the etched-in portion to be formed to form an opening portion; an etching-in step where a part of the etched-in portion is formed by removing the nitride semiconductor layer under the opening portion formed in the opening portion forming step. Further, in the waveguide forming step, the nitride semiconductor layers of the wafer including the part of the etched-in portion formed thereon and the dielectric mask are removed to form the stripe-shaped waveguide and to etch in the etched-in portion more deeply.

According to the present invention, near the end surface of the resonator, the etched-in portion can stop a step which begins to appear on the end surface of the resonator during cleaving. Accordingly, it is possible to prevent the step from developing at the stripe-shaped waveguide where laser light is emitted. In this way, it is possible to prevent damage to the end surface of the laser emission portion, and it is thus possible to fabricate a nitride semiconductor laser device that can emit laser light with satisfactory reliability even after being driven for a long time.

Moreover, according to the invention, the reduced influence of the Stark effect and the increased crystal asymmetry in the quantum well plane are expected to increase the gain, and moreover the suppression of the penetrating dislocation, which tends to develop in the C-axis direction, developing in the lamination direction is expected to enhance crystallinity, and hence to reduce the threshold current density. In addition, because the a-surface nitride semiconductor substrate can make the most of the excellent characteristics of the nitride semiconductor device, it is possible to provide a nitride semiconductor laser device that is laminated on the a-surface semiconductor substrate, highly reliable and has high-performance device characteristics.

### BRIEF DESCRIPTION OF THE DRAWINGS

FIG. 1 is a sectional view of a wafer illustrating a fabrication procedure of a nitride semiconductor laser device according to the invention;

FIG. 2 is a perspective view of the wafer illustrating the fabrication procedure of the nitride semiconductor laser device according to the invention;

FIG. 3 is a top view of the wafer illustrating a structure after the application of a resist mask in the fabrication procedure of the nitride semiconductor laser device according to the invention;

FIG. 4 is a top view of the wafer illustrating another structure after the application of a resist mask in the fabrication procedure of the nitride semiconductor laser device according to the invention;

FIG. 5 is a perspective view of the wafer illustrating the fabrication procedure of the nitride semiconductor laser device according to the invention;

FIG. 6 is a perspective view of the wafer illustrating the fabrication procedure of the nitride semiconductor laser device according to the invention;

FIG. 7 is a perspective view of the wafer illustrating the fabrication procedure of the nitride semiconductor laser device according to the invention;

FIG. 8 is a perspective view of the wafer illustrating the fabrication procedure of the nitride semiconductor laser device according to the invention;

FIG. 9 is a perspective view of the wafer illustrating the fabrication procedure of the nitride semiconductor laser device according to the invention;

FIG. 10 is a perspective view of the wafer illustrating the fabrication procedure of the nitride semiconductor laser device according to the invention;

FIG. 11 is a perspective view of the wafer illustrating a structure of the nitride semiconductor laser device according to the invention;

FIG. 12 is a top view of a wafer illustrating the pattern of a resist mask used in the fabrication procedure of the nitride semiconductor laser device according to a first embodiment of the invention;

FIG. 13 is a perspective view illustrating the structure of the nitride semiconductor laser device according to the first embodiment of the invention;

FIG. 14 is a top view of a wafer illustrating the pattern of a resist mask used in the fabrication procedure of the nitride semiconductor laser device according to a second embodiment of the invention;

FIG. 15 is a perspective view illustrating the structure of the nitride semiconductor laser device according to the second embodiment of the invention;

FIG. 16 is a top view of a wafer illustrating the pattern of a resist mask used in the fabrication procedure of the nitride semiconductor laser device according to a third embodiment of the invention;

FIG. 17 is a perspective view illustrating the structure of the nitride semiconductor laser device according to the third embodiment of the invention;

FIG. 18 is a top view of a wafer illustrating the pattern of a resist mask used in the fabrication procedure of the nitride semiconductor laser device according to a fourth embodiment of the invention;

FIG. 19 is perspective view illustrating the structure of the nitride semiconductor laser device according to the fourth embodiment of the invention;

FIG. 20 is an enlarged schematic view of a cleaved end surface of a nitride semiconductor laser device as a reference sample;

FIG. 21 is a top view of a wafer illustrating a relationship between an etched-in portion and a ridge stripe of the nitride semiconductor laser device according to the invention;

### DETAILED DESCRIPTION OF PREFERRED EMBODIMENTS

Hereinafter, embodiments of the present invention will be described with reference to the accompanying drawings. Structures of the nitride semiconductor laser devices according to the embodiments are explained in detail by describing the fabrication procedures.

Formation of individual layers by epitaxial growth: As for the nitride semiconductor laser devices according to the embodiments, on the surface of an n-type GaN substrate 101 having the (11-20) plane (also called the a plane) as the principal plane for crystal growth, by a crystal growth technology such as MOCVD (metal-organic chemical vapor deposition), nitride semiconductors are grown epitaxially to form individual nitride semiconductor layers.

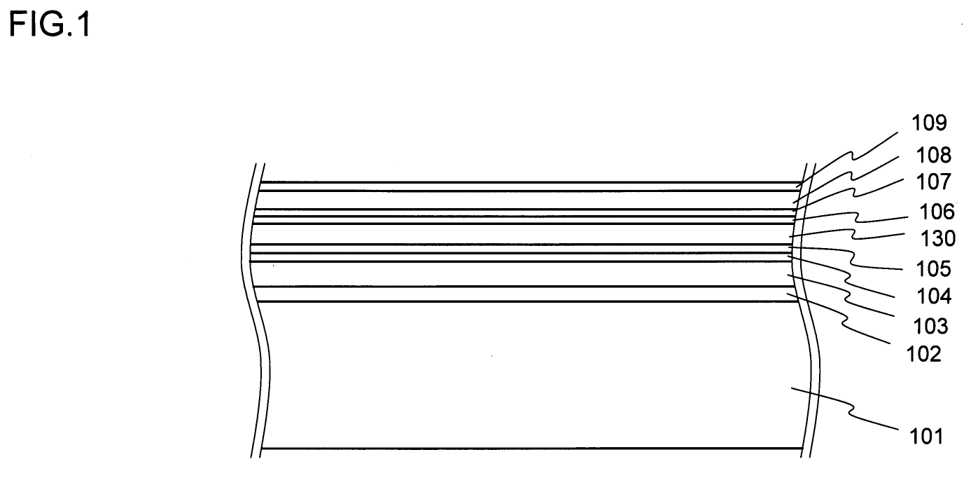

Specifically, as shown in FIG. 1, on the first principal plane of the n-type GaN substrate 101, the individual layers are laminated in the following order: an n-type GaN lower contact layer 102 having a thickness of 0.1 to 10 μm (for example, 4 μm); an n-type AlGaN lower clad layer 103 (with an aluminum content of about 0 to 0.3, for example, 0.02) having a thickness of 0.5 to 3.0 μm (for example, 2.0 μm); an n-type GaN lower guide layer 104 having a thickness of 0 to 0.3 μm (for example, 0.1 μm); an active layer 105 having a multiple quantum well layer structure composed of alternately laminated Inₓ₁Ga₁₋ₓ₁N quantum well layers and Inₓ₂Ga₁₋ₓ₂N barrier layers (where x1>x2≧0); a GaN intermediate layer 130 having a thickness of 0.01 to 0.1 μm (for example, 0.03 μm); a p-type AlGaN evaporation prevention layer 106 (with an aluminum content of about 0.05 to 0.4, for example, 0.2) having a thickness of 0.01 to 0.1 μm (for example, 0.03 μm); a GaN upper guide layer 107 having a thickness of 0 to 0.2 μm (for example, 0.01 μm); a p-type GaN upper clad layer 108 (with an aluminum content of about 0 to 0.3, for example, 0.02) having a thickness of 0.3 to 2 μm (for example, 0.5 μm); and a p-type GaN upper contact layer 109.

The lower clad layer 103 and the upper clad layer 108 may be formed of, instead of AlGaN, any material that meets the desired optical characteristics, such as a superlattice structure of GaN and AlGaN, a superlattice structure of GaN and InAlN, or a combination of several layers of AlGaN having different compositions. In a case where the oscillation wavelength is as short as 430 nm or less, it is preferable, in terms of light confinement, that the average Al content of the lower clad layer and the upper clad layer be about 0.02 or more. However, the lower clad layer 103 and the upper clad layer 108 can be formed of GaN by making the well layers of the active layer 105 thick, or by forming the barrier layers of the active layer 105, the lower guide layer 104 and the upper guide layer 107 with InGaN having a high index of refraction. On the other hand, in a case where the oscillation wavelength is as long as 430 nm or more, GaN or AlGaN containing less Al is preferably used.

The lower guide layer 104, the upper guide layer 107, and the GaN intermediate layer 130 may be formed of, instead of GaN described above, InGaN or AlGaN, or may be omitted if the design does not require them. The active layer 105 is designed to emit light of a wavelength of about 405 nm through an appropriate setting of the compositions of the quantum well layers and barrier layers and the structure in which these are laminated alternately.

The evaporation prevention layer 106 may be formed of any composition other than AlGaN, or may be doped with impurities such as As, P, or the like, so long as it serves to prevent the degradation of the active layer 105 during the time of its growth to the growth of the upper clad layer 108. Depending on the conditions under which the active layer 105 and the upper clad layer 108 are formed, the evaporation prevention layer 106 itself may be omitted. The upper contact layer 109 may be formed of, instead of GaN, InGaN, GaInNAs, GaInP, or the like.

Formation of contact electrode: After a wafer having the laminated nitride semiconductor layers thereon as shown in FIG. 1 is obtained by epitaxially growing each nitride semiconductor on the n-type GaN substrate 101, a first p electrode 112a containing Pd, Ni, or the like as its main content is formed over the entire surface of the wafer by vacuum deposition. Specifically, over the entire surface of the upper contact layer 109, which is the topmost layer in FIG. 1, the p-electrode 112a is formed. In each embodiment described below, the p electrode 112a is formed by vacuum-depositing Pd to a thickness of 300 Å.

After the p electrode 112a is formed by vacuum deposition, heat treatment (p electrode alloy process) is applied to the metal of the p electrode 112a to alloy it. The p electrode alloy process is preferably carried out at a temperature of 300 to 800° C., in an ambiance such as vacuum or an inert gas of nitrogen or the like. Besides these ambiances, the heat treatment may be carried out in an ambiance containing a small amount of oxygen. In each embodiment described below, the p electrode alloy process is performed at 500° C., for 10 minutes.

Then, by photolithography, on the surface of the p-electrode 112a, a stripe-shaped resist mask having a width of 0.5 to 30 μm (for example, 20 μm) is formed. The stripe pattern of this stripe-shaped resist corresponds to the waveguide shape of the nitride semiconductor laser device and, on the wafer where the p electrode 112a is formed, a large number of such stripes are formed in parallel to one another. In each embodiment described below, the stripe-shaped resists are formed in the [0001] direction (c-axis direction) or in the [1-100] direction (m-axis direction).

Subsequently, by ion etching or wet etching, the parts of the p-electrode 112a are removed except the parts under the stripe-shaped resists. Thus the p electrode 112a is formed on the regions only under the stripe-shaped resists that are formed at equal intervals on the wafer which includes the nitride semiconductor layers formed by epitaxial growth on the n-type GaN substrate 101. In each embodiment described below, as the etching process for the stripe-shaped resists formed over the p electrode 112a, Pd wet etching is performed using a mixture of nitric acid and hydrochloric acid.

The p-electrode 112a may be formed simultaneously with a pad electrode 112b which will be formed later. In that case, on the surface of the wafer having the laminate structure of the nitride semiconductor layers as shown in FIG. 1, the resists may be formed directly, and then the process of forming a pad electrode may be performed as described below.

Forming a dielectric mask for an etched-in portion: A dielectric mask 120 composed of SiO₂ having a thickness of 0.1 μm to 0.5 μm (e.g. 0.2 μm) is formed on the entire surface of the wafer on which the stripe-shaped resists are formed at equal intervals as described above. Then, after the stripe-shaped resists are dissolved with a solvent, the dielectric mask 120 is removed together with the stripe-shaped resists by ultrasonic cleaning.

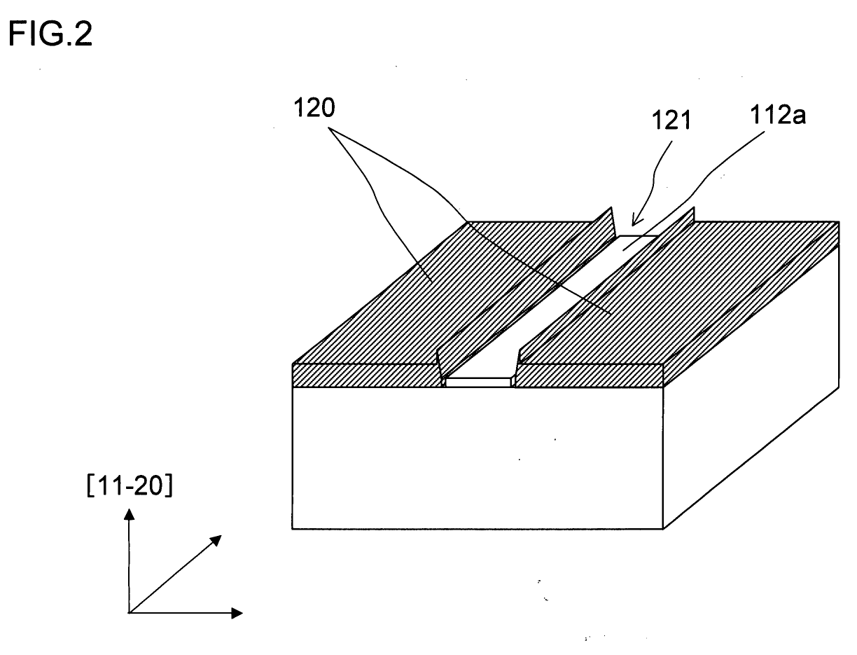

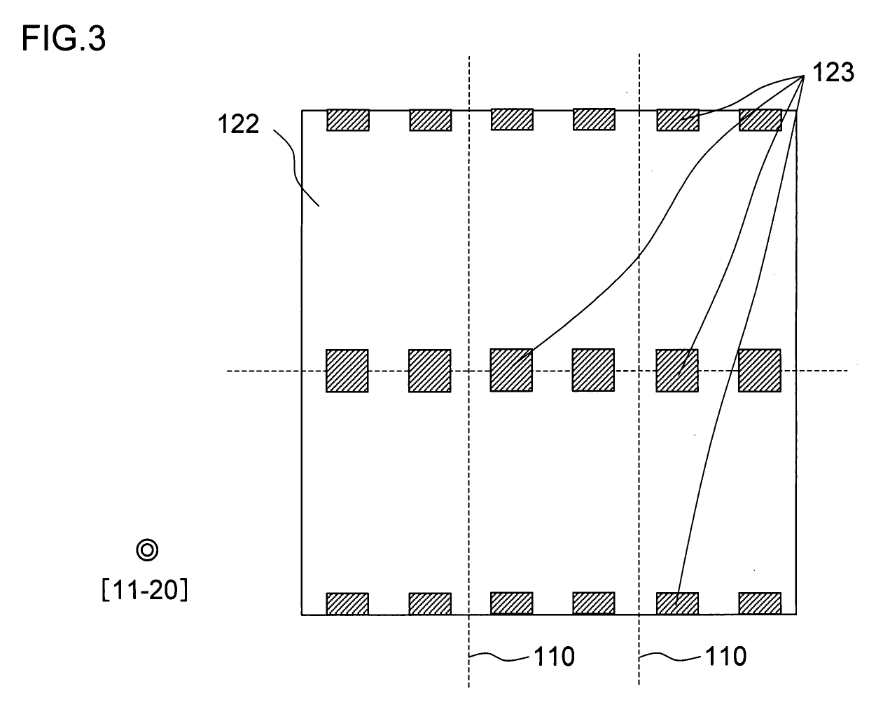

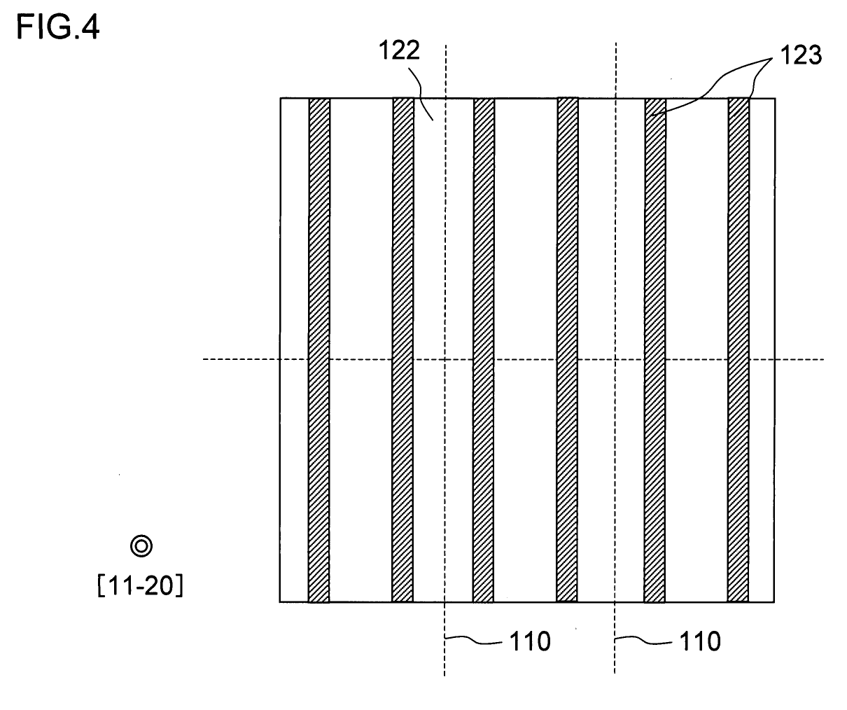

Thus, as shown in FIG. 2, the dielectric masks 120 are formed between the stripe-shaped p electrodes 112a which are formed at equal intervals. In other words, a stripe-shaped opening portion 121 having a width of 20 μm is formed through the dielectric mask 120. Then, a resist mask 122 is coated on the entire surface of the dielectric mask 120 having the stripe-shaped opening portion 121. After that, as shown in FIGS. 3 and 4, opening portions 123 are formed at equal intervals through the resists by photolithography. FIGS. 3 and 4 is a top view showing the resist mask 122 having the opening portions 123.

The opening portions 123 of the resist mask 122 shown in FIGS. 3 and 4 are formed on the dielectric mask 120. Specifically, the opening portions 123 of the resist mask 122 are formed through the regions except the stripe-shaped opening portions 121, where the p electrodes 112a are formed, of the dielectric mask 120. Thus, because the opening portions 123 are formed on the stripe-shaped dielectric mask 120, the opening portions 123 of the resist mask 122 shown in FIG. 3 and 4 are formed at equal intervals in the width direction of the stripe-shaped dielectric mask 120.

The opening portions 123 of the resist mask 122 shown in FIG. 3 are also formed at equal intervals in the longitudinal direction of the stripe of the dielectric mask 120 and has a rectangular shape. The opening portions 123 are so spaced that the distance between their central positions is equal to the length of the resonators of the nitride semiconductor laser devices. The opening portion 123 of the resist mask 122 shown in FIG. 4 has a stripe shape along the longitudinal direction of the stripe-of the dielectric mask 120.

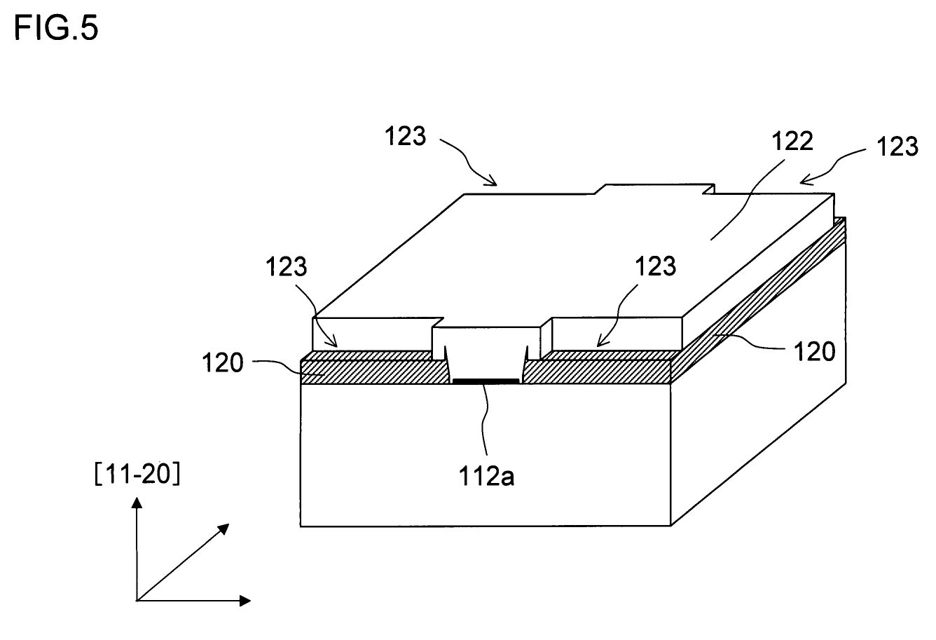

Hereinafter, each step is explained based on the rectangular opening portion 123 shown in FIG. 3 as an example. As shown in the perspective view of FIG. 5, in a discrete semiconductor laser device, the opening portions 123 are formed at four corners with respect to the central position of the waveguide on which the p electrode 112a is formed.

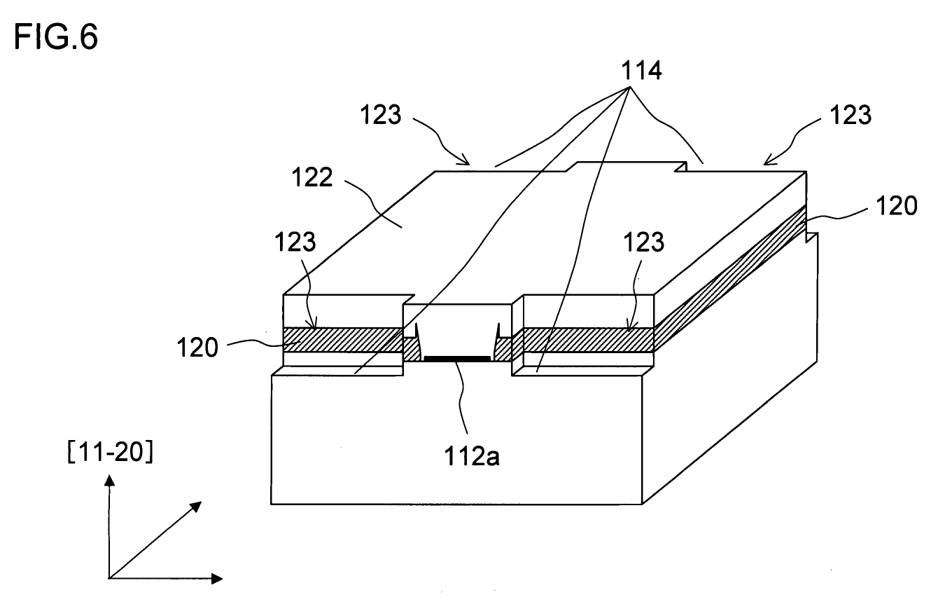

Forming an etched-in portion: After the resist mask 122 having the opening portion 122 is formed on the wafer as described above, the dielectric mask 120 under the opening portion 123 is removed by dry etching or wet etching. Dry etching is further applied to the nitride semiconductor layer under the dielectric mask 120 removed under the opening portion 123. Thus, as shown in the perspective view of FIG. 6, the dielectric mask 120 and the nitride semiconductor layer under the opening portion 123 are removed and an etched-in portion 114 is formed. After the etched-in portion is formed, the resist mask 122 is removed. In each embodiment described below, dry etching is applied to the nitride semiconductor layer about 0.25 μm deep.

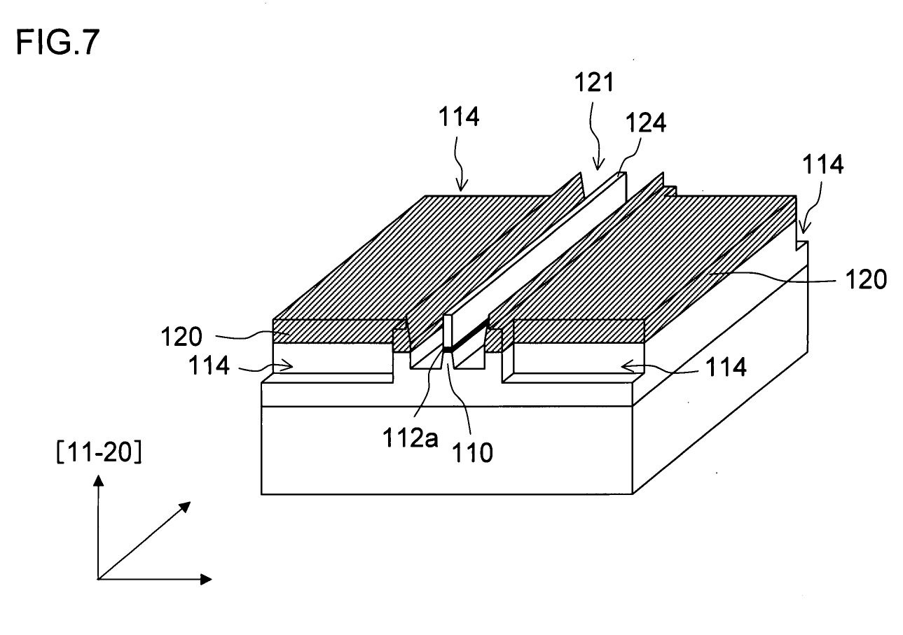

Forming a ridge stripe: Then, by photolithography, on the surface of the p-electrode 112a, a stripe-shaped resist 124 having a width of 0.5 to 30 μm (for example, 1.5 μm) is formed as shown in FIG. 7. FIG. 7 is a perspective view showing the wafer structure after dry etching is applied. This stripe-shaped pattern of the resist 124 corresponds to the waveguide of the semiconductor laser device, and, on the wafer, a large number of such stripes are formed in parallel to one another. Dry etching is applied to the p electrode 112a through the resist 124 and the dielectric mask 120.

Thus, the p-electrode 112a is removed except the part under the stripe-shaped resist 124. Specifically, as shown in the perspective view of FIG. 7, only the p electrode 112a under the resist 124 used as the mask remains and has a width of 0.5 to 30 μm (e.g, 1.5 μm) equal to the width of the resist 124. If the p electrode 112a is not formed, dry etching process can be omitted. In this case, the resist 124 is formed directly on the nitride semiconductor layer exposed through the opening portion 121 of the dielectric mask 120 formed on the wafer which has the etched-in portion 114. Then, the next process is carried out as described below.

Through the resist 124 and the dielectric mask 120, dry etching relying on reactive plasma using SiC₄ or Cl₂ gas is applied to the nitride semiconductor to form a ridge stripe 110. As shown in FIG. 2, because the opening portion 121 of the dielectric mask 120 is a stripe having a width of 20 μm, dry etching is applied to both sides of the ridge stripe 110. At the same time, because an opening portion over the etched-in portion 114 is already made through the dielectric mask 120 in the forming process of the etched-in portion as described above, the nitride semiconductor layer under this opening portion is further etched.

As for the laminated structure of the nitride semiconductor layers shown in FIG. 1, dry etching is applied to both sides of the ridge stripe 110 so deeply that the upper clad layer 108 having a thickness of 0.00 μm to 0.20 μm remains. Thus a difference in the lateral index of refraction is given to the ridge stripe 110 and an index-of-refraction type of waveguide can be obtained. After this etching, the upper contact layer 109 and the upper clad layer 108 protrude from the other regions, and the ridge stripe 110 composed of the upper contact layer 109 and the upper clad layer 108 is formed.

Because the nitride semiconductor layer is already etched 0.25 deep to form the etched-in portion 114 in the forming process of the etched-in portion as described above, etching is applied to the active layer 105 or further to the layer under the active layer 105. After the ridge stripe 110 is formed by dry etching, the dielectric mask 120 is removed. In each embodiment described below, the dielectric mask 120 made of SiO₂ is removed with fluoric acid.

The effect of the present invention is especially great when the etched-in portion 114 reaches the active layer 105. In other words, two requirements need to be met: the ridge stripe has a desired ridge height; the etched-in portion 114 reaches the active layer 105. Therefore, a dry etching amount of the nitride semiconductor layers need to be optimized depending on the each layer thickness of the active layer 105, the evaporation prevention layer 106, the upper guide layer 107, the upper clad layer 108, and the upper contact layer 109. Specifically, in the forming process of the etched-in portion, the etching is applied from the lowest position of the upper clad layer 108 of the ridge stripe 110 to the active layer 105 or further to the layer under the active layer 105.

Forming a burying layer: Over the entire surface of the wafer thus having such ridge stripe 110 formed on it at predetermined intervals, a layer of SiO₂ having a thickness of 0.1 μm to 0.5 μm (for example, 0.3 μm) is formed as a burying layer 111 to bury the ridge stripe 110. Here, on the burying layer 111 formed of SiO₂, there may be additionally formed one or more layers for enhancing the adhesion with the pad electrode 112b, which will be described later. The layer, or layers, for enhancing the adhesion with the pad electrode 112b is formed by use of an oxide such as TiO₂, ZrO₂, HfO₂, or Ta₂O₅, or a nitride such as TiN, TaN, or WN, or a metal such as Ti, Zr, Hf, Ta, or Mo.

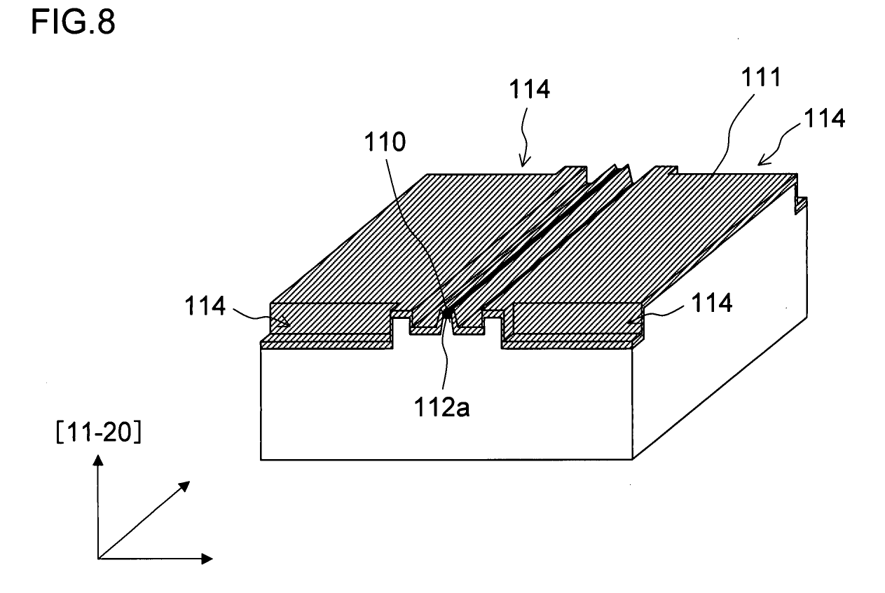

Subsequently, the resist 124 formed on the ridge stripe 110 is dissolved with a solvent and is then removed by ultrasonic cleaning or the like, and along with the resist 124, the burying layer 111 formed on the top surface of the resist 124 is removed. Through this process, as shown in the perspective view of FIG. 8, the burying layer 111 is formed on the region where the ridge stripe 110 is not formed, while the surface of the p electrode 112a is exposed as the top surface of the ridge stripe 110. In a case where the p-electrode 112a is not formed, when the resist 124 is dissolved, the surface of the upper contact layer 109 is exposed as the top surface of the ridge stripe 110.

Formation of a pad electrode: Through the etching and the formation of the burying layer 111 as described above, the wafer having the region where the burying layer 111 is formed and the ridge stripe 110 where the burying layer 111 is not formed is obtained. Next, by photolithography, a resist is formed for the patterning of the pad electrode 112b, which will be formed as a p-electrode subsequently. Formed here is a resist (unillustrated) so patterned as to have openings formed in a matrix-like array, with each opening so located and sized as to show the ridge stripe 110 amply at the center. Specifically, the resist has such openings formed discontinuously both in the direction in which the ridge stripe 110 extends and in the direction perpendicular to it.

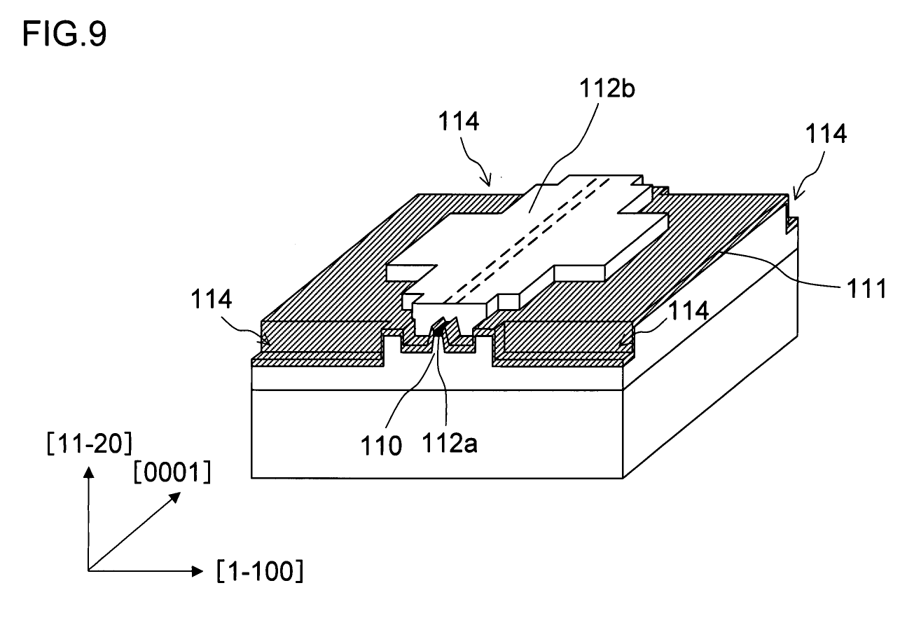

Then, on the surface of the wafer having the resist formed on it, layers of Mo/Au, or W/Au, or the like are formed in this order by vacuum deposition or the like, so that a pad electrode 112b serving as a p-electrode as shown in FIG. 9 is formed in contact with a large part of the p-electrode 112a formed on the surface of the ridge stripe 110. In a case where the p-electrode 112a is not formed before the formation of the ridge stripe 110, in the process of forming the pad electrode 112b, as a p-electrode via which electric power is supplied from outside, layers of Ni/Au, or Pd/Mo/Au, or the like are formed instead.

Subsequently, the resist is dissolved with a solvent and is then lifted off by ultrasonic cleaning or the like so that, along with the resist, the metal film formed on the top surface of the resist is removed. Thus, the pad electrode 112b is formed to have the same shape as the opening in the resist. The opening in the resist may be given a desired shape taking the wire-bonding region or the like into account.

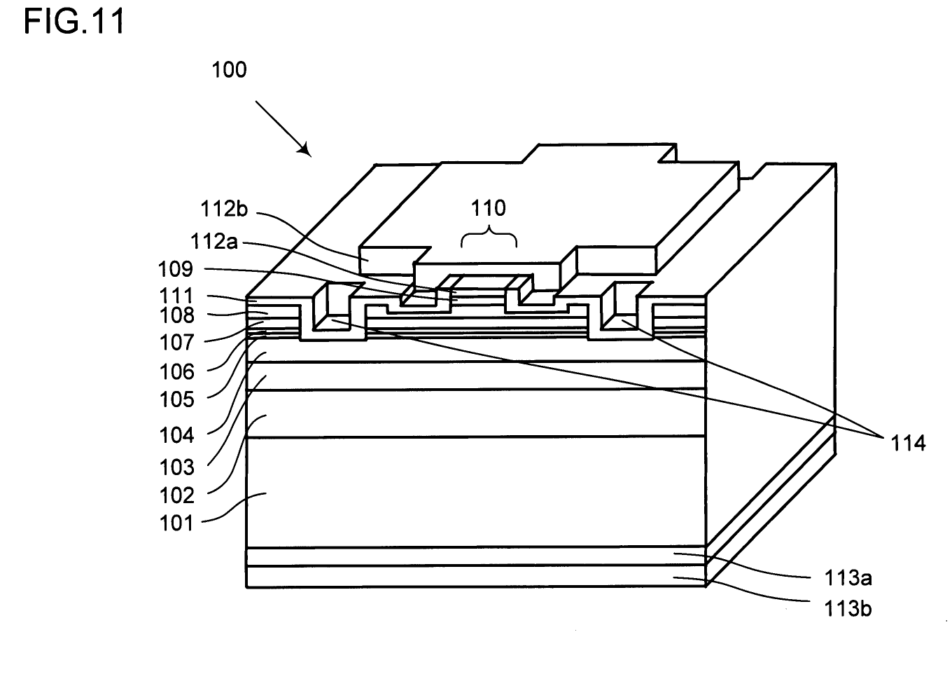

If the pad electrode 112b is formed to reach the splitting surface along which the wafer is split into individual nitride semiconductor laser devices 100 (see FIG. 11), or to be close to the position where the etched-in portion 114, which will be described later, is formed in the following process, there is a risk of current leakage and electrode exfoliation. It is to avoid these inconveniences that the pad electrode 112b is patterned as described above. The pad electrode 112b may be patterned by the selective plating method instead of the liftoff technique. It may even be patterned by etching, in which case, first, a metal film as the material for a p-electrode is vacuum-deposited over the entire surface of the wafer, then, by photolithography, the part of the metal film to be left behind as the pad electrode 112b is protected with a resist, and then the metal film is patterned with an aqua regia-based etchant to form the pad electrode 112b.

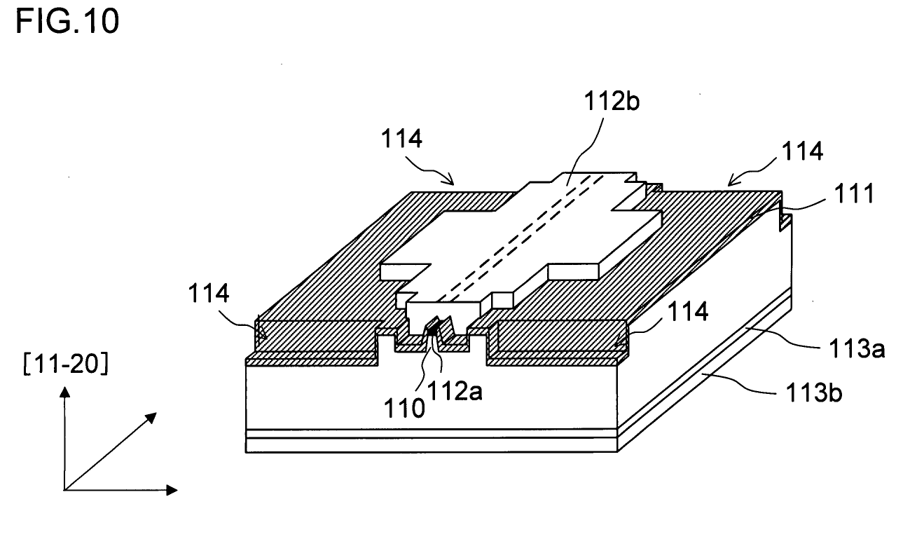

Formation of an n-side electrode: The bottom surface (the bottom surface of the n-type GaN substrate 101) of the wafer having the pat electrode 112b formed in it is ground and polished until the wafer has a thickness of 60 to 150 μm (for example, 100 μm). Then, on the bottom surface (the ground and polished surface) of the wafer, layers of Hf/Al and Ti/Al, are formed in this order by vacuum deposition or the like, so that an n-electrode 113a is formed as shown in FIG. 10. Then, to secure the ohmic characteristics of the n-electrode 113a, heat processing is performed. Then, to facilitate the mounting of the nitride semiconductor laser devoice 100 (see FIG. 11) when it is mounted, a metallized electrode 113b is formed by vapor-depositing a metal film of Au or the like so as to cover the n-electrode 113a as shown in the perspective view of FIG. 10.

Formation of a mirror surface: After the formation of the n-electrode 113a and the metallized electrode 113b on the bottom surface of the wafer as described above, scribe lines (straight-line scratches) are formed partly along the splitting lines, and the wafer is then cleaved in a direction substantially perpendicular to the ridge stripe 110 into a plurality of bars each having a width of 300 to 2,000 μm (for example, 800 μm), the width thus being the length of a resonator (cavity).

Typically, the scribe lines are formed at one edge of the wafer, but may be formed at a plurality of positions along the splitting lines so that cleaving into bars takes place precisely along the splitting lines. In either case, the cleaving starts at the scribe lines and advances in one direction, eventually achieving cleaving into bars. The cleavage surfaces form resonator end surfaces. The thickness of the wafer is adjusted to be so small as to permit precise cleaving. To carry out the cleaving to obtain the bars, the scribe lines are formed through scratching achieved by diamond-point scribing or laser scribing.

Chosen as the splitting surface between the bars is, of all the cleavage surfaces of a nitride semiconductor having a wurtzite structure, one perpendicular to the laminated surface. In a case where the substrate having the (11-20) plane as its principal plane is used as described in this embodiment, one choice of the cleavage surface is the (0001) plane when the ridge stripe 110 is formed in [0001] direction (c-axis direction) as shown in the first and second embodiments described later. Likewise, when the ridge stripe 110 is formed in the [1-100] direction (m-axis direction), the (1-100) plane is chosen as the cleavage surface.

Then, on the resonator end surafces at opposite sides of each bar composed of a plurality of nitride semiconductor laser devices 100 (see FIG. 11) contiguous with one another, coating films are formed. The front-side and rear-side coating films are each so structured as to have a desired reflectance. For example, on the rear-side resonator end surface, a high-reflection film (unillustrated) is formed that is composed of two or more layers laminated; on the front-side resonator end surface, a low-reflection film (unillustrated) is formed that is composed of one or more layers laminated, such as a coating film containing 5% of alumina. This permits the laser light excited inside each of the nitride semiconductor laser devices 100 (see FIG. 11) split from the bar to be emitted through the front-side resonator end surface.

Splitting into individual laser chips: The bar thus having reflective films formed on the resonator end surfaces is then split into individual chips having a width of about 200 to 300 μm, and thus the nitride semiconductor laser device 100 shown in FIG. 11 is obtained. Here, the splitting is performed at the splitting positions so chosen as not to affect the ridge stripe 110, for example in such a way that the ridge stripe 110 is located at the center of the nitride semiconductor laser device 10.

Although the nitride semiconductor laser device shown in FIG. 11 100 has the entire etched-in portions 114 at its both sides, it may have a part of the etched-in portions 114 at its both sides as shown in FIG. 10. Besides, the device 100 may have at least a part of one of the etched-in portions 114 formed at both sides of the ridge stripe 110, or may have a structure that the etched-in portions 114 formed at both sides of the ridge stripe 110 are cut off.

The nitride semiconductor laser device 100 thus split and thereby obtained is then mounted on a stem, and is electrically connected via wires from outside to the pad electrode 112b serving as a p-electrode and to the metallized electrode 113b serving as an n-electrode. Then the nitride semiconductor laser device 100 mounted on the stem is sealed with a cap put on the stem, and is thereby provided as a semiconductor laser apparatus.

The characteristics of the nitride semiconductor laser device 100 obtained by splitting the wafer having the etched-n portion 114 as described above are evaluated in each embodiment explained below. In the following embodiments, structure examples of the nitride semiconductor laser device 100 and the evaluation results of the characteristics of the device 100 having the structures are explained.

### Embodiment 1

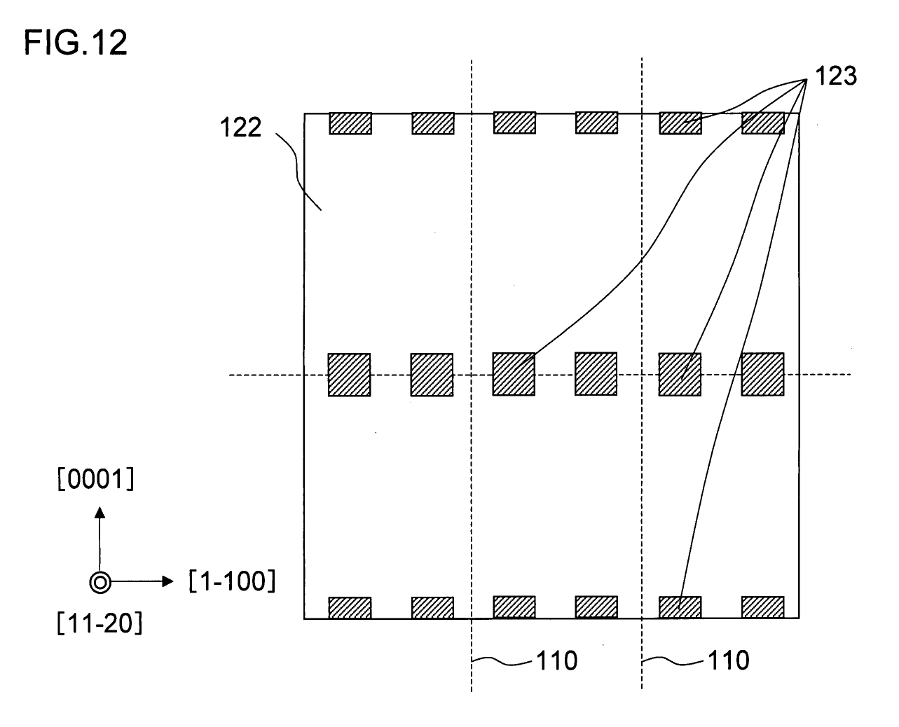

By use of the [0001] direction (c-axis direction) as the direction in which the striped-shape resist is formed on the p electrode 112a and each process described above, the nitride semiconductor laser device 100 according to this embodiment is made. As shown in FIG. 12, the resist mask 122 to form the etched-in portion 114 is provided with the stripe-shaped opening portions 123 that are formed at equal intervals in both [0001] direction (c-axis direction) and [1-100] direction (m-axis direction) as shown in FIG. 3. The rectangular openings 123 are formed on the scribe lines extending in the [1-100] direction (m-axis direction) in which the wafer is cleaved into the bars to obtain the mirror surfaces (resonator end surfaces).

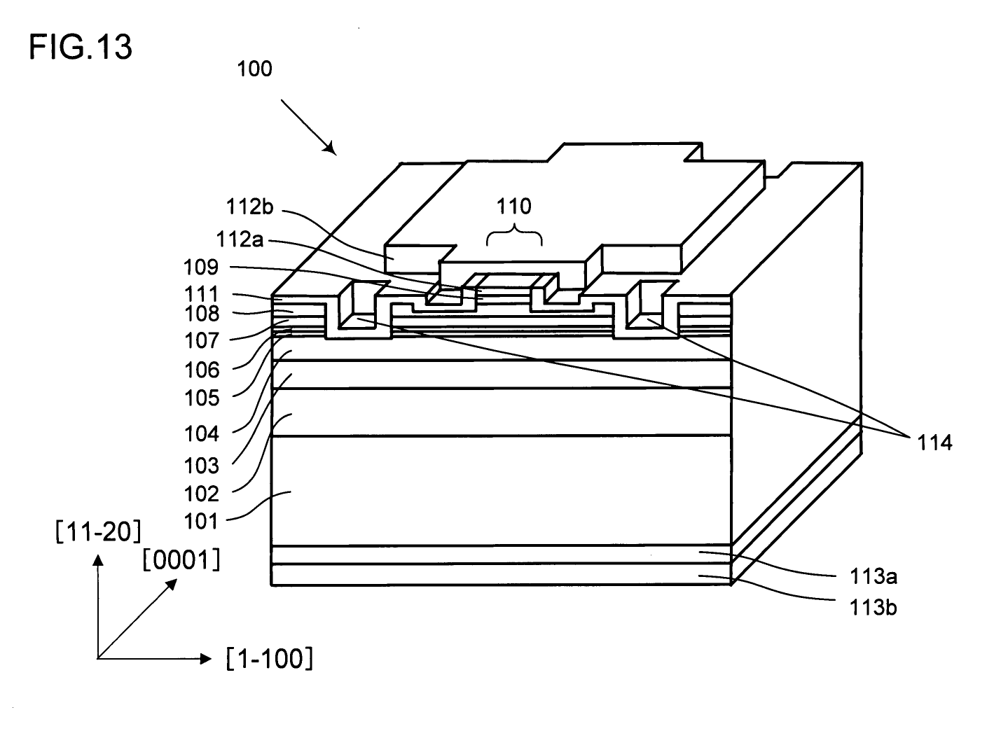

In the forming process of the mirror surface in this embodiment, because the ridge stripe is formed in the [0001] direction (c-axis direction) of the GaN substrate 101 having (11-20) plane as its principal plane, the (0001) plane (c plane) is used as the cleavage surface. Therefore, as shown in the perspective view of FIG. 13, the nitride semiconductor laser device 100 has the ridge stripe 100 extending in [0001] direction (c-axis direction) and the etched-in portions 114 are disposed at the four corners with respect to the central position of the ridge stripe 110.

### Embodiment 2

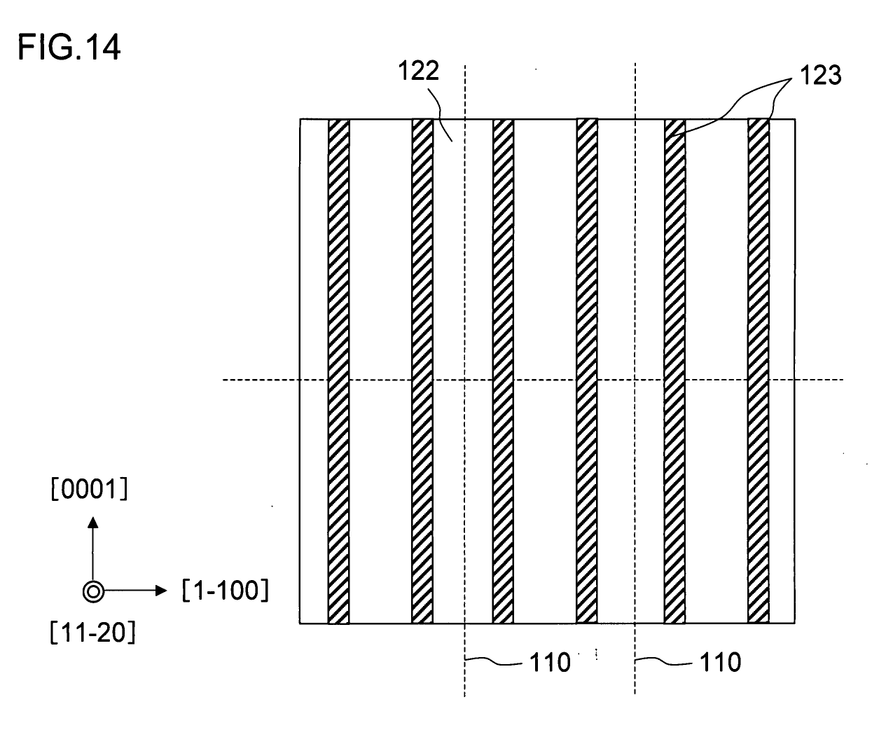

In the same way as in the first embodiment, by use of the [0001] direction (c-axis direction) as the direction in which the striped-shape resist is formed on the p electrode 112a and each process described above, the nitride semiconductor laser device 100 according to this embodiment is also made. Accordingly, the (0001) plane (c plane) is used as the cleavage surface of the nitride semiconductor laser device 100. Specifically, the resist mask 122 to form the etched-in portion 114 is provided with the stripe-shaped opening portions 123 as shown in FIG. 14 that extend in the [0001] direction (c-axis direction) and are formed at equal intervals in the [1-100] direction (m-axis direction) as shown in FIG. 4.

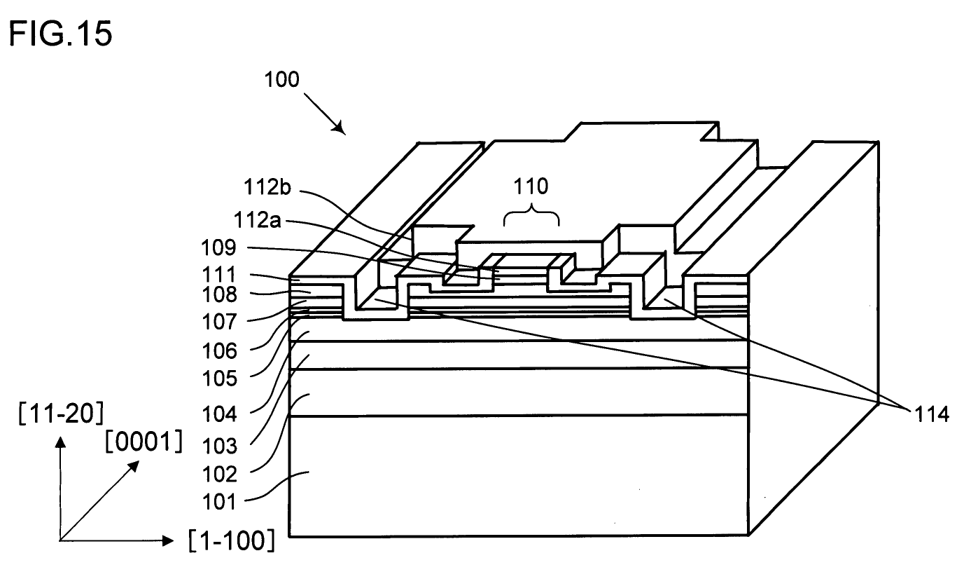

In this embodiment, the stripe-shaped etched-in regions 114 each having a width of 70 μm are formed on both sides of and in parallel with the ridge stripe 110 at the positions away from the center of the 20-μm-wide stripe which has the ridge stripe 110 at its center. Accordingly, as shown in the perspective view of FIG. 15, the nitride semiconductor laser device 100 according to this embodiment has the ridge stripe 110 extending in the [0001] direction (c-axis direction) and the etched-in portions 114 are formed on both sides of and in parallel with the ridge stripe 110 with respect to the center of the ridge stripe 110.

### Embodiment 3

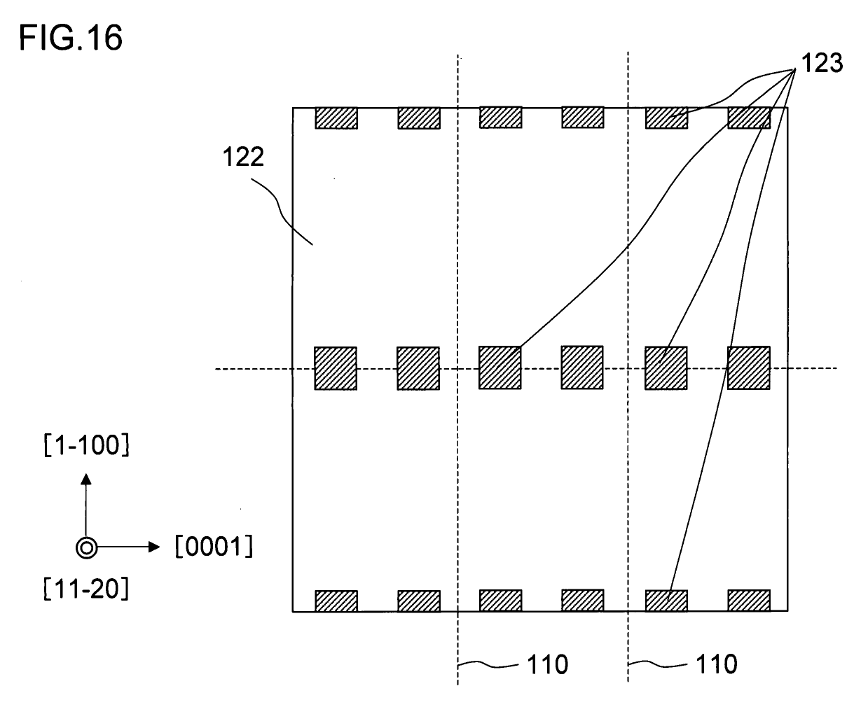

Unlike the first embodiment, the nitride semiconductor laser device 100 is made by use of the [1-100] direction (m direction) in which the stripe-shaped resist is formed on the p electrode 112a and each process described above. The resist mask 122 to form the etched-in portion 114 is provided with the stripe-shaped opening portions 123 as shown in FIG. 16 that are formed at equal intervals in both [0001] direction (c-axis direction) and [1-100] direction (m-axis direction) as shown in FIG. 3. The rectangular openings 123 are formed on the scribe lines extending in the [0001] direction (c-axis direction) in which the wafer is cleaved into the bars to obtain the mirror surfaces (resonator end surfaces).

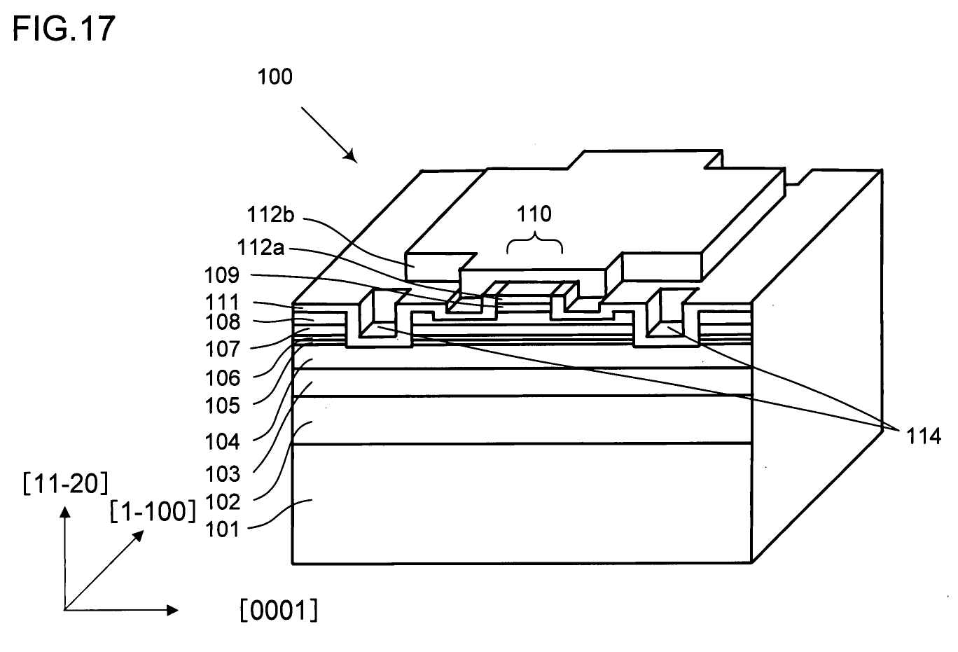

In the forming process of the mirror surface in this embodiment, because the ridge stripe is formed in the [1-100] direction (m-axis direction) of the GaN substrate 101 having (11-20) plane as its principal plane, the (1-100) plane (m plane) is used as the cleavage surface. Therefore, as shown in the perspective view of FIG. 17, the nitride semiconductor laser device 100 has the ridge stripe 100 extending in [1-100] direction (m-axis direction) and the etched-in portions 114 are disposed at the four corners with respect to the central position of the ridge stripe 110.

### Embodiment 4

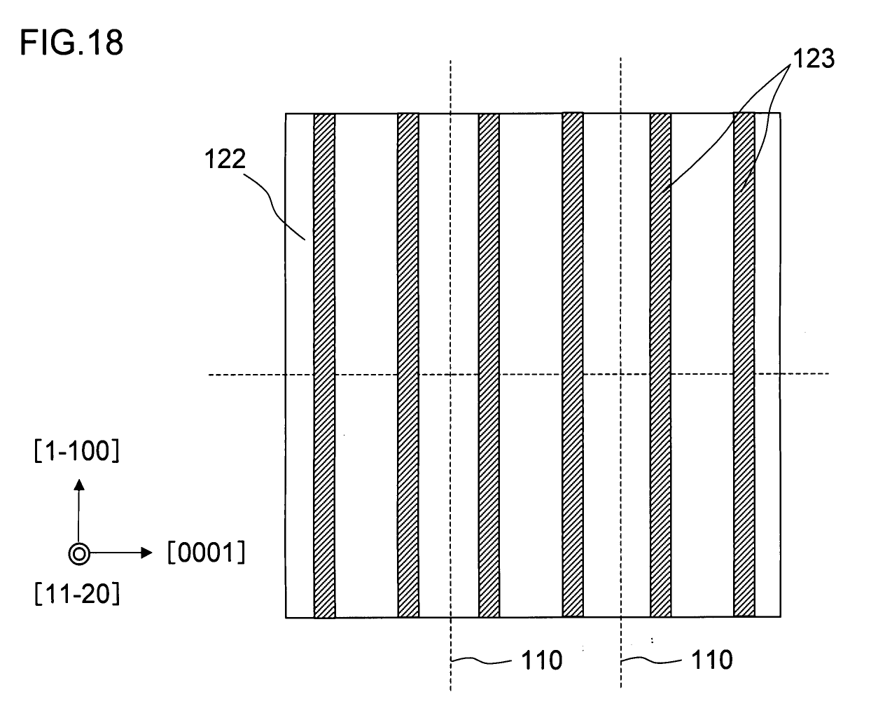

Like the third embodiment, the nitride semiconductor laser device 100 is made by use of the [1-100] direction (m direction) in which the stripe-shaped resist is formed on the p electrode 112a and each process described above. Accordingly, the (1-100) plane (m plane) is used as the cleavage surface of the nitride semiconductor laser device 100. Specifically, the resist mask 122 to form the etched-in portion 114 is provided with the stripe-shaped opening portions 123 as shown in FIG. 18 that extend in the [1-100] direction (m-axis direction) and are formed at equal intervals in the [0001] direction (c-axis direction) as shown in FIG. 4.

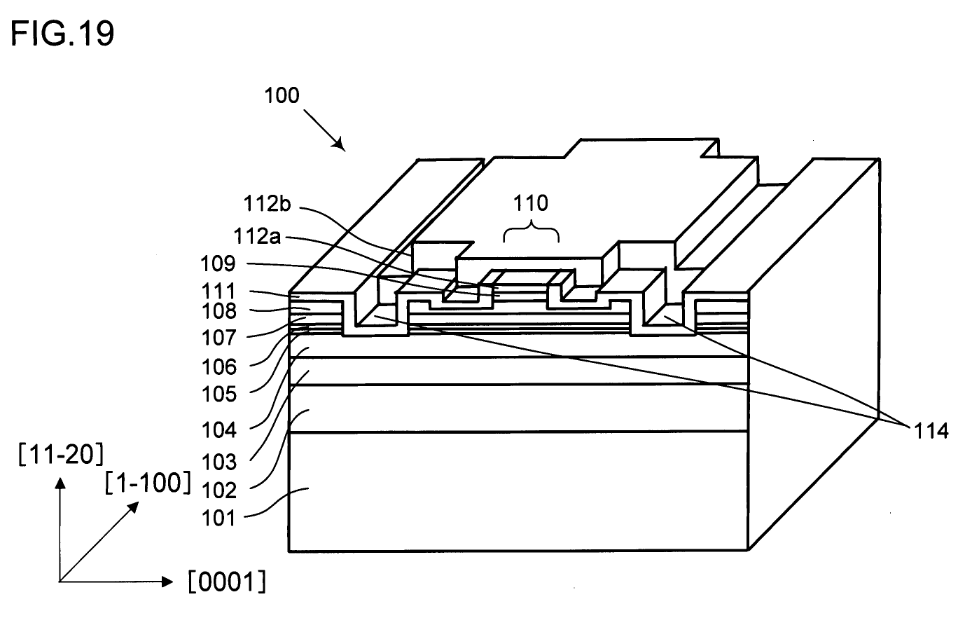

Like the second embodiment, in this embodiment, the stripe-shaped etched-in regions 114 each having a width of 70 μm are formed on both sides of and in parallel with the ridge stripe 110 at the positions 70 μm away from the center of the ridge stripe 110. Accordingly, as shown in the perspective view of FIG. 19, the nitride semiconductor laser device 100 according to this embodiment has the ridge stripe 110 extending in the [1-100] direction (m-axis direction) and the etched-in portions 114 are formed on both sides of and in parallel with the ridge stripe 110 with respect to the center of the ridge stripe 110.

Evaluation of the characteristics of the embodiments and reference samples: Evaluations conducted with the nitride semiconductor laser devices 100 having the structures described in the first to fourth embodiments revealed that they yielded an optical output of about 600 mW in CW (continuous wave) driving. Further increasing the driving current resulted in device breakdown, and thus it was impossible to obtain any higher optical output. A close observation of the breakdown revealed that the crystal was blown out at the light-emission-side surface of the waveguide, mechanically destroying the resonator end surface. Thus, the device was evaluated to have a COD (catastrophic optical damage) of about 600 mW.

On the other hand, as a reference sample, a nitride semiconductor laser device was fabricated in the same manner as the above nitride semiconductor laser device 100 except that no etched-in portion 114 was formed. This reference sample was evaluated to have a COD of about 150 mW, obviously inferior to the nitride semiconductor laser devices 100 according to the embodiments of the present invention.

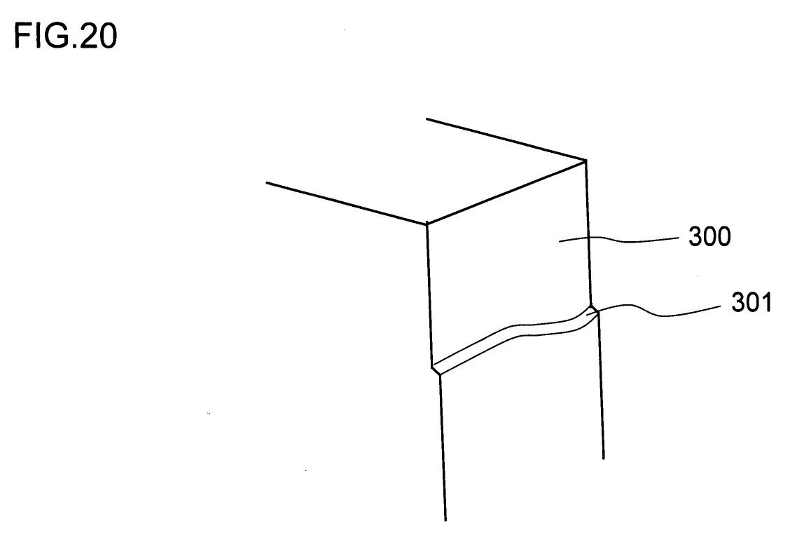

Analysis: With the reference sample, the cleavage surface 300 of the bar after cleaving was closely observed under an SEM (scanning electron microscope). As shown in FIG. 20, the observation revealed that, at a position near the active layer, an extremely small step (unflushness) of about 0.1 μm or less had developed in parallel to the laminated surface. Such step 301 is not so influential as to hamper the oscillation of a nitride semiconductor laser device, and is so small that it can be detected only by a close analysis; it has therefore not been conventionally known to be present in a nitride semiconductor laser device that was made in the conventional way. By contrast, with the bars after the cleaving of the wafers on which the nitride semiconductor laser devices 100 are arranged in the first to fourth embodiments, hardly any such step 301 shown in FIG. 20 was observed on the cleaving surface near the waveguide (the ridge stripe 110), and the cleaving surface was thus flat.

Thus, the invention suppresses the phenomenon that, in a semiconductor laser device having a structure in which nitride semiconductors are laminated on the (11-20) plane, cleaving at a surface perpendicular to the (11-20) plane develops the step 301 shown in FIG. 20.

In general, in a nitride semiconductor laser device, the active layer 105 is formed of a material having a small energy gap combined with a comparatively large lattice constant (for example, InGaN), and the guide layers 104, 107, and the clad layers 103, 108 contiguous with the active layer 105 are formed of a material having a large energy gap combined with a comparatively small lattice constant (for example, GaN or AlGaN). Thus, the active layer 105 contains strain attributable to the difference in the lattice constant. Moreover, understandably, the material of the active layer 105 differs also in mechanical properties from the materials of the guide layers 104, 107 and the clad layers 103, 108.

Thus, when an attempt is made to cleave such a laminate structure in its entirety at a surface perpendicular to the (11-20) plane, supposedly, while the layers above and below the active layer 105 split together, the active layer 105, containing InGaN, splits with a slight deviation, and, as the cleaving advances in one direction, the deviation accumulates to develop a step. By contrast, as for the nitride semiconductor laser devices 100 according to the first to fourth embodiments of the present invention, in the etched-in region 114, however, the region corresponding to the splitting surface is etched in from the surface of the wafer to the region under the active layer 105. Thus, the etched-in portion 114 prevents transmission of impact waves, and thereby stops the step 301 shown in FIG. 20 so that it will not run beyond.

Thus, unless a step develops between the etched-in portion 114 and the ridge stripe 110 during the cleaving, it is possible to greatly reduce the incidence of the step 301 shown in FIG. 20 that develops in parallel to the nitride semiconductor layers near the active layer 105 between the etched-in portion 114 and the ridge stripe 110.

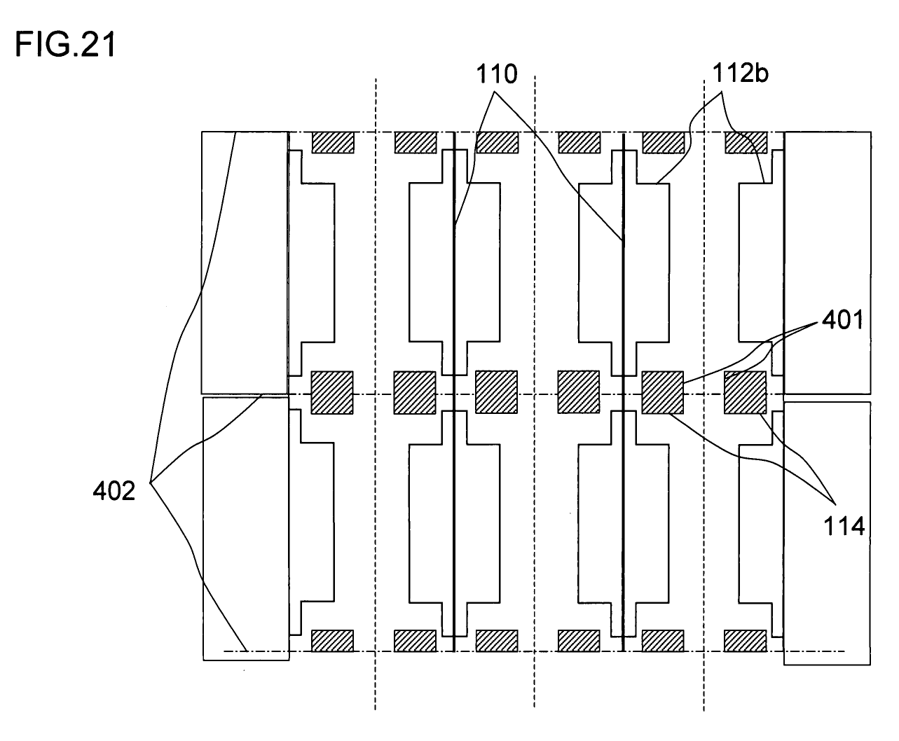

When the etched-in portion 114 is formed in this way, it is preferable that the etched-in portion 114 be located at a distance of 2 μm or more away from the edge of the ridge stripe 110. Specifically, as shown in FIG. 21, if the etched-in portion 114 is located at a distance of 2 μm or less away from the edge 401 of the etched-in portion 114, the structure of the etched-in portion 114 affects the optical characteristics of the nitride semiconductor laser device 10. On the other hand, locating the etched-in portion 114 unduly far away lessens the effect of stopping the step 301 shown in FIG. 20. Thus, it is appropriate that the etched-in portion 114 be formed at a distance of 200 μm or less away from the edge 401 of the ridge stripe 110, so as to prevent the development of the step 301 shown in FIG. 20 on the resonator end surface after the cleavage between the edge 401 of the etched-in portion 114 and the ridge stripe 110.

Furthermore, it is preferable that the distance from the bottom surface of the active layer 105 to the bottom surface of the etched-in portion 114 be less than 1 μm at least at part of the designed splitting line 402. Etching in unduly deep may cause, at that position, a deviation of the cleavage surface across the entire thickness of the wafer from its top to bottom side.

In this embodiment, the etched-in portion 114 is formed on each side of the ridge stripe 110 as shown in FIG. 21; in principle, however, it may be provided only on one side of the upstream side with respect to the direction in which the cleaving advances. So long as the etched-in portion 114 is located in front of the ridge stripe 110 with respect to the direction in which impact waves travel during the cleaving (so long as the etched-in portion 114 is formed between the splitting groove and the ridge stripe 110), it is possible to obtain the effect of the invention.

Forming the etched-in portion 114 on each side of the ridge stripe 110, however, is convenient because it permits the cleaving to be performed on either side. In particular, in a case where the wafer suffers chipping or the like during the process, whereas it is difficult to form a scribe line on the side where the chipping occurred, it is possible to form one on the side opposite from the planned side. Thus, forming the etched-in portion 114 on each side of the ridge stripe 110 leads to higher productivity.

When the wafer is split into bars, to prevent an unexpected deviation in the width of bars (a deviation in the length of laser resonators), splitting grooves may be formed also in a middle portion of the wafer (a plurality of scribe lines may be formed on a single line). In this case, impact waves may travel in non-uniform directions along the splitting line (the cleaving may occur in the opposite direction in a small part of the wafer). Thus, to surely prevent development of the parallel step 301 shown in FIG. 20 near the active layer 105 and thereby increase yields, it is preferable that the etched-in portion 114 be formed on each side of the ridge stripe 110.

In the embodiment described above, the etched-in portion 114 is formed on the splitting line only near the ridge stripe 110, and the etched-in portions 114 are formed at positions corresponding to the four corners of the nitride semiconductor laser device 110. The etched-in portion 114 may instead be formed over the entire surface except the surface near the ridge stripe 110 by etching under the conditions mentioned previously.

The nitride semiconductor laser device according to the invention can be applied to semiconductor laser apparatuses used in various light source apparatuses such as optical pickups, liquid crystal displays, laser displays, illumination apparatuses, etc. For example, the nitride semiconductor laser device according to the invention can even be applied to broad area semiconductor laser apparatuses for illumination that, despite being subject to loose restrictions in terms of the control of optical characteristics such as FFP (far-field pattern), yield an extremely high output of several watts.

In a broad area semiconductor laser apparatus, its high output puts much strain on the resonator end surface of the nitride semiconductor laser device. This makes it essential that no step develops on the resonator end surface as in the nitride semiconductor laser device according to the invention. Accordingly, preventing a step by forming an etched-in portion by the side of the ridge stripe in the nitride semiconductor laser device used in a broad area semiconductor laser apparatus is expected to lead to higher reliability. In this broad area semiconductor laser apparatus, it is preferable that the ridge stripe of the nitride semiconductor laser device has a width of 5 to 100 μm.

Moreover, the nitride semiconductor laser device according to the invention can be applied not only to those having a stripe-shaped waveguide of the ridge type as described above but also to those having a stripe-shaped waveguide of any other type, such as a BH (buried hetero) type or RiS (ridge by selective re-growth) type. In a semiconductor laser device of the BH type, except for the regions from the top surface of the evaporation prevention layer to the bottom surface of the etched-in portion, each layer may be so formed as to have a thickness of 0.03 μm to 0.05 sum. Furthermore, the nitride semiconductor laser device according to the invention can also be applied in cases where the p- and n-types in the structure described above are reversed and the waveguide is formed on the n-type semiconductor side. Besides, a single nitride semiconductor laser device may be provided with a plurality of stripe-shaped waveguides.

The nitride semiconductor laser device according to the invention can be applied to semiconductor laser apparatuses used in various light source apparatuses such as optical pickups, liquid crystal displays, laser displays, illumination apparatuses, etc.

What is claimed is:

1. A nitride semiconductor laser device comprising:
a nitride semiconductor substrate;
a plurality of nitride semiconductor layers laminated on a surface of the nitride semiconductor substrate and including an active layer;
a stripe-shaped waveguide formed on the nitride semiconductor layers; and
a resonator end surface formed of the cleaved surfaces of the nitride semiconductor layers, together with the nitride semiconductor substrate,
wherein
a principal plane of the nitride semiconductor substrate is a (11-20) plane,
the resonator end surface is perpendicular to the principal plane, and
in a cleavage surface forming the resonator end surface, at least by one side of the stripe-shaped waveguide, an etched-in portion is formed as an etched-in region open toward a surface of the nitride semiconductor layers.

2. The nitride semiconductor laser device according to claim 1,
wherein a direction in which the stripe-shaped waveguide is formed is a [0001] direction and a cleavage surface forming the resonator end surface is a (0001) plane.

3. The nitride semiconductor laser device according to claim 1,
wherein a direction in which the stripe-shaped waveguide is formed is a [1-100] direction and a cleavage surface forming the resonator end surface is a (1-100) plane.

4. The nitride semiconductor laser device according to claim 1,
wherein the etched-in portion is formed at a distance of 2 μm or more but 200 μm or less from the stripe-shaped waveguide.

5. The nitride semiconductor laser device according to claim 1,
wherein the etched-in portion is so formed on a cleavage line as to have a rectangular shape when forming the resonator end surface.

6. The nitride semiconductor laser device according to claim 1,
wherein the etched-in portion is so formed as to have a stripe shape parallel to the stripe-shaped waveguide.

7. The nitride semiconductor laser device according to claim 1,
wherein a protection film is formed on the surface of the etched-in portion

8. The nitride semiconductor laser device according to claim 1, comprising a plurality of the stripe-shaped waveguides.

9. A method of fabricating a nitride semiconductor laser device comprising the steps of:
laminating a plurality of nitride semiconductor layers including an active layer on a nitride semiconductor substrate having a (11-20) surface as a principal plane for crystal growth;
forming a stripe-shaped waveguide on the nitride semiconductor layers;
forming an etched-in portion in the nitride semiconductor layers as an etched-in region open toward a surface of the nitride semiconductor layers;
forming, in part of a wafer having the stripe-shaped waveguide and the etched-in portion formed thereon and therein, a groove to serve as a starting point of cleavage; and
applying an external force to the wafer along the groove to form a cleavage surface perpendicular to the principal plane,
wherein the etched-in portion is formed at a position by a side of the stripe-shaped waveguide where the cleavage surface cuts.

10. The method of fabricating a nitride semiconductor laser device according to claim 9,
wherein the forming step of the etched-in portion including the steps of:
masking the regions with a dielectric layer except the region of the stripe-shaped waveguide on the plurality of the nitride semiconductor layers laminated in the laminating step;
forming an opening portion by removing the dielectric layer located at the forming position of the etched-in portion;
forming a part of the etched-in portion by removing the nitride semiconductor layers under the opening portion formed in the forming step of the opening portion;
wherein the stripe-shaped waveguide is formed by removing the nitride semiconductor layers of the wafer having the part of the etched-in portion formed in the forming step of the etched-in portion and the dielectric mask, and the etched-in portion is etched in further deep.
